(19) United States
(12) Patent Application Publication
(10) Pub. No.: US 2025/0073963 A1
(43) Pub. Date: Mar. 6, 2025

(54) IMPRINT APPARATUS, IMPRINT METHOD, INFORMATION PROCESSING APPARATUS AND ARTICLE MANUFACTURING METHOD

(71) Applicant: CANON KABUSHIKI KAISHA, Tokyo (JP)

(72) Inventor: RYO NAWATA, Tochigi (JP)

(21) Appl. No.: 18/810,614

(22) Filed: Aug. 21, 2024

(30) Foreign Application Priority Data
Sep. 1, 2023 (JP) 2023-142378

(51) Int. Cl. B29C 43/18; B29C 43/02; B29C 43/34; B29C 43/58; G03F 7/00; G03F 9/00

(52) U.S. Cl. CPC B29C 43/18; B29C 43/021; B29C 43/58; G03F 7/0002; G03F 9/7042; B29C 2043/025; B29C 43/34; B29C 2043/5825; B29C 2043/5875

(57) ABSTRACT

An imprint apparatus for forming, by using a mold, a pattern of an imprint material on a layer formed on a surface pattern existing in a substrate, the apparatus including a calculation unit configured to output, based on information indicating a relationship among a geometric shape of the surface pattern, a thickness of the layer, a film thickness of the imprint material existing between the mold and the layer in a state in which the mold is in contact with the imprint material, and a shearing force generated in the imprint material in the state, a target film thickness of the imprint material required for generating the target shearing force in the imprint material, if the geometric shape of the surface pattern, the thickness of the layer, and a target shearing force are input.

### BACKGROUND OF THE INVENTION

### Field of the Invention

The present invention relates to an imprint apparatus, an imprint method, an information processing apparatus and an article manufacturing method.

### Description of the Related Art

As a lithography technique for manufacturing an article such as a semiconductor device or a Micro Electro Mechanical System (MEMS), an imprint technique that molds an imprint material on a substrate using a mold is known. The imprint technique is a technique of forming a pattern of an imprint material on a substrate by curing the imprint material in a state in which the imprint material arranged (supplied) on the substrate is in contact with a mold, and separating the mold from the cured imprint material.

In the imprint technique, a photo-curing method is one of curing methods for curing the imprint material. The photo-curing method is a method of curing an imprint material by irradiating it with light (such as ultraviolet light) while the imprint material arranged on a substrate is in contact with a mold.

In a process of manufacturing a semiconductor device, a plurality of patterns are overlapped. Therefore, it is necessary to align a mold and a substrate so as to align the position of the pattern formed in the mold and the position of the shot region (underlying pattern) formed in the substrate.

The alignment accuracy between the mold and the substrate is also called the overlay accuracy. Japanese Patent Laid-Open No. 2017-212439 proposes a technique for improving the overlay accuracy in the imprint apparatus employing the imprint technique. Japanese Patent Laid-Open No. 2017-212439 discloses a technique of adjusting the density of the imprint material arranged on the substrate in accordance with the unevenness of the surface of the substrate since the distortion of the mold occurring due to the unevenness of the surface of the substrate when bringing the mold into contact with the imprint material on the substrate causes degradation of the overlay accuracy. According to this technique, the distortion of the mold occurring due to the influence of the unevenness of the surface of the substrate is reduced so that degradation of the overlay accuracy can be suppressed.

In the conventional technique, by adjusting the density of the imprint material arranged on the substrate in accordance with the relatively large unevenness existing in the surface of the substrate, more specifically, the undulation of the substrate equal to or larger than several hundred μm, the distortion of the mold is reduced and degradation of the overlay accuracy is suppressed.

However, the conventional technique does not consider the relatively small unevenness existing in the surface or the substrate, more specifically, the depth of the underlying pattern of about several tens of nm formed in the surface of the substrate, the thickness of the underlying layer formed on the substrate (underlying pattern), and the residual film thickness of the imprint material. These depth and thicknesses influence a shearing force generated in the imprint material in a state in which a mold is in contact with the imprint material on the substrate. For example, if the residual film thickness of the imprint material is too large, the shearing force decreases, resulting in a large relative vibration between the mold and the substrate and degradation of the overlay accuracy. On the other hand, if the residual film thickness of the imprint material is too small, the shearing force increases, resulting in occurrence of a distortion and degradation of the overlay accuracy. In this manner, the conventional technique may not always be sufficient to suppress degradation of the overlay accuracy.

### SUMMARY OF THE INVENTION

The present invention provides an imprint apparatus advantageous in suppressing degradation of the overlay accuracy between a mold and a substrate.

According to one aspect of the present invention, there is provided an imprint apparatus that performs an imprint process of forming, by using a mold, a pattern of an imprint material on a layer formed on a surface pattern existing in a substrate, the apparatus including an obtainment unit configured to obtain information indicating a relationship among a geometric shape of the surface pattern, a thickness of the layer, a film thickness of the imprint material existing between the mold and the layer in a state in which the mold is in contact with the imprint material, and a shearing force generated in the imprint material in the state, and a control unit configured to control the imprint process, wherein the control unit includes a calculation unit configured to, if the geometric shape of the surface pattern, the thickness of the layer, and a target shearing force are input, output a target film thickness of the imprint material required for generating the target shearing force in the imprint material based on the information obtained by the obtaining unit, and controls supply of the imprint material onto the layer such that the film thickness of the imprint material in the state achieves the target film thickness in the imprint process.

Further aspects of the present invention will become apparent from the following description of exemplary embodiments with reference to the attached drawings.

### BRIEF DESCRIPTION OF THE DRAWINGS

FIG. 1A is a schematic view illustrating configurations of an imprint apparatus according to an aspect of the present invention.

FIG. 1B is a schematic view illustrating configurations of an imprint apparatus according to an aspect of the present invention.

FIG. 2 is a flowchart for describing an operation of the imprint apparatus.

FIGS. 3A and 3B are views each showing the section including a mold, a substrate, an underlying layer, and an imprint material.

FIG. 4 is a view showing an example of data tables.

FIG. 5 is a view showing an example of the functional modules of a control unit.

FIG. 6A is a view showing the relationship between the displacement of an XY stage and a shearing force.

FIG. 6B is a view showing the relationship between the displacement of an XY stage and a shearing force.

FIGS. 7A to 7F are views for describing an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

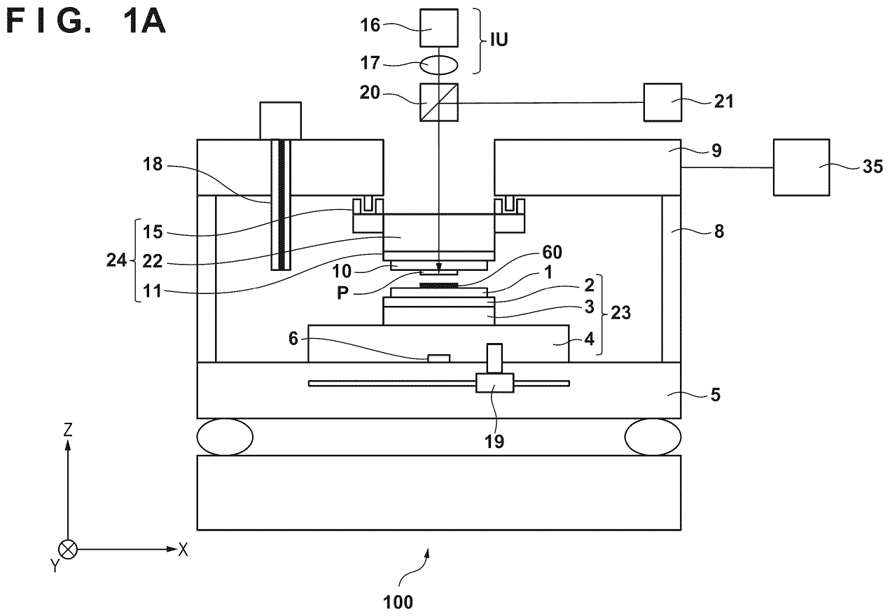

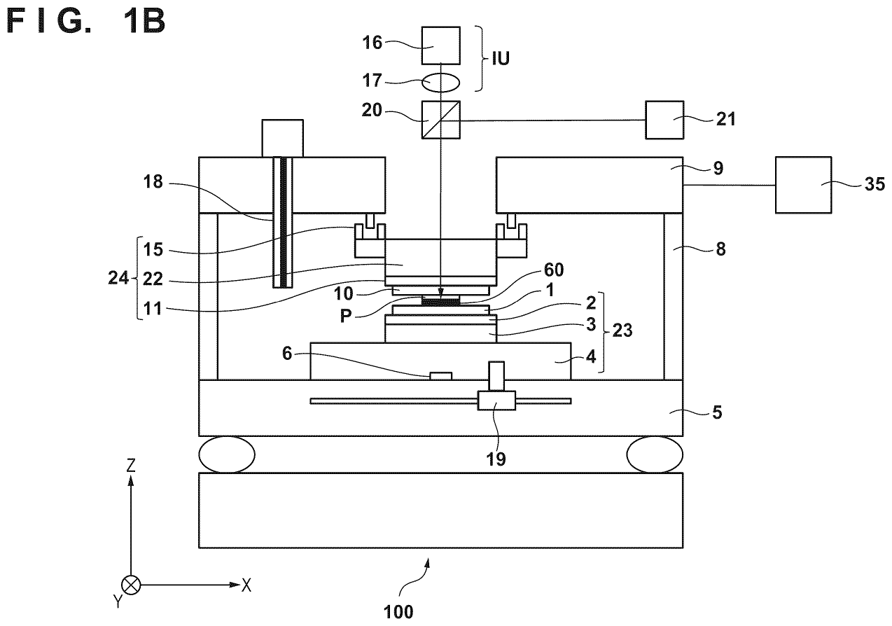

FIGS. 1A and 1B are schematic views each illustrating configurations of an imprint apparatus 100 according to an aspect of the present invention. FIG. 1A shows a state before a mold is brought into contact with the imprint material on a substrate, and FIG. 1B shows a state in which the mold is in contact with the imprint material on the substrate. The imprint apparatus 100 is, for example, a lithography apparatus which is employed in a lithography process as a manufacturing process of a device such as a semiconductor device, a liquid crystal display device, or a magnetic storage medium as an article, and forms a pattern on a substrate. The imprint apparatus 100 performs an imprint process in which an imprint material on a substrate (on a layer formed on the surface pattern existing in the substrate) is molded using a mold to form a pattern of the imprint material on the substrate. In this embodiment, the imprint apparatus 100 brings the mold into contact with the imprint material arranged (supplied) on the substrate and applies curing energy to the imprint material, thereby forming a pattern of a cured product to which the pattern of the mold is transferred.

As the imprint material, a material (curable composition) to be cured by receiving curing energy is used. An example of the curing energy that is used is electromagnetic waves, heat, or the like. As the electromagnetic waves, for example, infrared light, visible light, ultraviolet light, and the like selected from the wavelength range of 10 nm (inclusive) to 1 mm (inclusive) is used.

The curable composition is a composition cured by light irradiation or heating. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising of a sensitizer, a hydrogen donor, an internal mold release agent, a surfactant, an antioxidant, a polymer component, and the like.

The imprint material may be applied in a film shape onto the substrate by a spin coater or a slit coater. The imprint material may be applied, onto the substrate, in a droplet shape or in an island or film shape formed by connecting a plurality of droplets using a liquid injection head. The viscosity (the viscosity at 25° C.) of the imprint material is, for example, 1 mPa·s (inclusive) to 100 mPa·s (inclusive).

As the substrate, glass, ceramic, a metal, a semiconductor, a resin, or the like is used, and a member made of a material different from that of the substrate may be formed on the surface of the substrate, as needed. More specifically, examples of the substrate include a silicon wafer, a semiconductor compound wafer, silica glass, and the like.

In the specification and the accompanying drawings, directions will be indicated on an XYZ coordinate system in which directions parallel to a plane on which the substrate is placed are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are OX, OY, and OZ, respectively.

In this embodiment, the imprint apparatus 100 employs, as the curing method of the imprint material, a photo-curing method in which the imprint material is cured by irradiating it with light such as ultraviolet light. However, the curing method is not limited to this.

As shown in FIGS. 1A and 1B, the imprint apparatus 100 includes a substrate holding unit 23 that holds a substrate 1, a supply unit 18 that supplies an imprint material 60, a mold holding unit 24 that holds a mold 10, an irradiation unit IU, a beam splitter 20, an image capturing unit 21, and a control unit 35. The imprint apparatus 100 also includes a base 5, a linear encoder 6, support columns 8, a top plate 9, and a linear motor 19.

The substrate holding unit 23 is a unit capable of holding and driving the substrate 1. The substrate holding unit 23 includes, for example, a substrate chuck 2, a θ stage 3 functioning as a rotational driving mechanism, and an XY stage 4 functioning as an XY driving mechanism. The substrate chuck 2 holds the substrate 1 by a vacuum chucking force or an electrostatic attraction force. The θ stage 3 has a function of adjusting (correcting) the position of the substrate 1 in the θZ (rotation about the Z-axis) direction. The θ stage 3 is arranged on the XY stage 4 configured to position the substrate 1 in the X direction and the Y direction. The XY stage 4 is driven in the X direction and the Y direction by the linear motor 19. The θ stage 3 and the XY stage 4 support the substrate chuck 2, and move the substrate 1 held by the substrate chuck 2. The XY stage 4 is placed on the base 5. The linear encoder 6 is attached on the base 5 in the X direction and the Y direction, and measures the position of the XY stage 4. The support columns 8 stand on the base 5 and support the top plate 9.

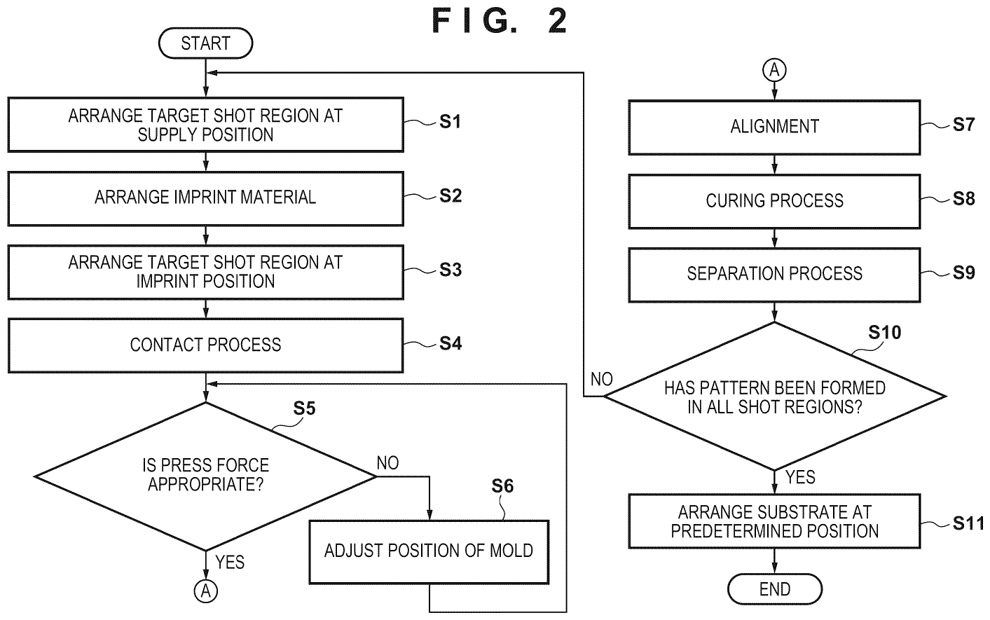

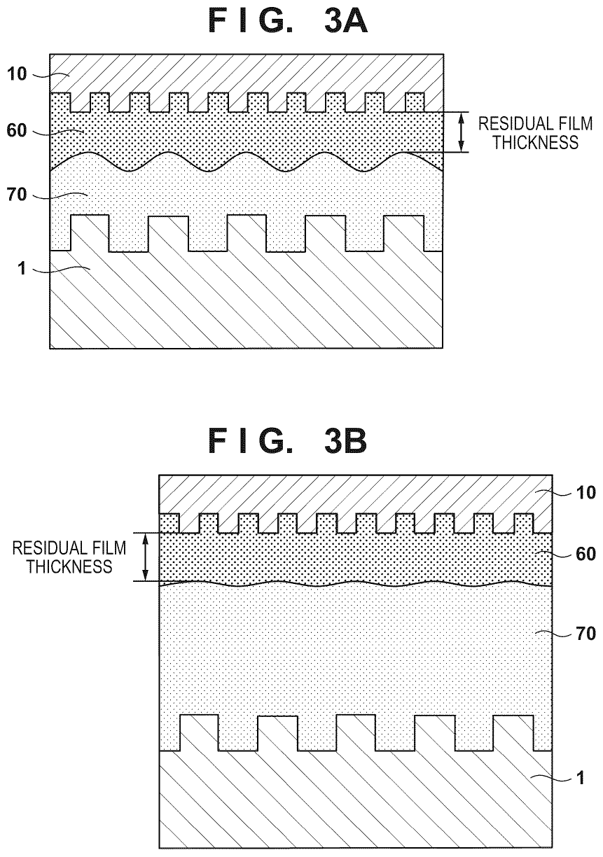

The substrate 1 includes, for example, a single-crystal silicon substrate, a Silicon On Insulator (SOI) substrate, and the like. In this embodiment, as will be described later with reference to FIGS. 3A and 3B, an underlying layer 70 has been formed on the surface of the substrate 1. The underlying layer 70 is a layer formed on the surface of the substrate 1. The underlying layer 70 includes, for example, Spin On Carbon (SOC), Spin On Glass (SOG), and the like, and may be formed from a plurality of films of SOC, SOG, and the like. The substrate 1 includes a plurality of shot regions, and the imprint material 60 is supplied from the supply unit 18 to each shot region. By repeating the imprint process of forming the pattern of the imprint material 60 for each shot region of the substrate 1, the pattern can be formed on the entire surface of the substrate 1.

The supply unit 18 has a function of arranging, on the substrate, the imprint material 60 (photo-curable composition) having a property of being cured by, for example, irradiation of ultraviolet light. The supply unit 18 is embodied as, for example, a dispenser that includes discharge nozzles and supplies the imprint material 60 onto the substrate by discharging the imprint material 60 (droplets thereof) from the discharge nozzles to the substrate 1. In this embodiment, the supply unit 18 supplies (arranges) the imprint material 60 onto the substrate by dropping the liquid imprint material 60 to the surface of the substrate 1. The amount of the imprint material 60 to be supplied onto the substrate 1 from the supply unit 18, that is, the supply amount of the imprint material 60 may be decided in accordance with the required film thickness and pattern density of the imprint material 60. The supply unit 18 is not necessarily provided in the imprint apparatus 100. A supply unit provided outside the imprint apparatus 100 may supply the imprint material 60 onto the substrate.

The mold 10 is also referred to as a mold, a template, or an original, and used to mold the imprint material 60 on the substrate. The mold 10 has, for example, a rectangular outer shape. The mold 10 includes, on the surface facing the substrate 1, a pattern region P where a concave-convex pattern to be transferred to the imprint material 60 on the substrate is three-dimensionally formed. The pattern region P is formed as a convex portion (mesa portion) of several tens of μm to several hundred μm to prevent the region of the mold 10 excluding the pattern region P (the region surrounding the pattern region P) from coming into contact with the substrate 1. The mold 10 is formed of a material that transmits light for curing the imprint material 60 on the substrate, which is ultraviolet light in this embodiment. For example, the mold 10 is formed of quartz or the like.

The mold holding unit 24 is a unit capable of holding and driving the mold 10. The mold holding unit 24 includes, for example, a mold chuck 11, a mold stage 22, and a linear actuator 15 functioning as a mold driving mechanism. The mold chuck 11 holds the mold 10 by a vacuum chucking force or an electrostatic attraction force. The mold stage 22 holds the mold chuck 11. The mold stage 22 has a function of adjusting (correcting) the position of the mold 10 in the Z direction, and a function of adjusting (correcting) the tilt of the mold 10. The linear actuator 15 drives the mold 10 held by the mold chuck 11 in the Z direction, thereby bringing the mold 10 into contact with the imprint material 60 on the substrate or separating the mold 10 from the imprint material 60 on the substrate. The linear actuator 15 includes, for example, an air cylinder or a linear motor. Each of the mold chuck 11 and the mold stage 22 includes an opening (not shown) which allows light from the irradiation unit IU to pass therethrough.

The irradiation unit IU includes, for example, a light source 16 and a collimator lens 17. In a curing process of curing the imprint material 60 on the substrate, the irradiation unit IU irradiates the substrate 1 (the imprint material 60 on the substrate) with light emitted from the light source 16 via the collimator lens 17. The light source 16 includes a mercury lamp or the like that emits ultraviolet light serving as light for curing the imprint material 60, for example, an i-line (wavelength of 365 nm).

The beam splitter 20 is arranged at the position where the optical path of the irradiation unit IU intersects the optical path of the image capturing unit 21. In this embodiment, the beam splitter 20 transmits the light for curing the imprint material 60, which is emitted from the irradiation unit IU, and reflects the light for observing the contact state of the mold 10, which is emitted from the image capturing unit 21. The image capturing unit 21 captures the pattern region P of the mold 10 via the beam splitter 20, thereby obtaining an image.

The control unit 35 is formed from an information processing apparatus (computer) including a CPU, a memory, and the like. The control unit 35 operates the imprint apparatus 100 by comprehensively controlling respective units of the imprint apparatus 100 in accordance with a program stored in a storage unit. The control unit 35 may be formed integrally with the imprint apparatus 100 (in a common housing), or may be formed separately from the imprint apparatus 100 (in another housing).

With reference to FIG. 2, an operation of the imprint apparatus 100, more specifically, an imprint process (imprint method) of forming a pattern of the imprint material 60 on the substrate will be described. The imprint process is performed by the control unit 35 comprehensively controlling respective units of the imprint apparatus 100.

In step S1, the shot region (to be referred to as the “target shot region” hereinafter) to be the target of the imprint process among the plurality of shot regions on the substrate is arranged at the supply position where the imprint material 60 is supplied. More specifically, by driving the XY stage 4, the substrate chuck 2 holding the substrate 1 is moved in the X direction and the Y direction to arrange the target shot region on the substrate at the supply position below the supply unit 18.

In step S2, the imprint material 60 is arranged (supplied) in the target shot region on the substrate. More specifically, droplets of the imprint material 60 are discharged from the supply unit 18 to the target shot region arranged at the supply position below the supply unit 18. With this, the imprint material 60 is arranged in the target shot region.

In step S3, the target shot region with the imprint material 60 arranged therein is arranged at the imprint position facing the pattern region P of the mold 10. More specifically, the XY stage and the 0 stage 3 are driven to move the substrate chuck 2 holding the substrate 1 in the X direction and the Y direction and adjust the position of the substrate 1 in the θZ direction, thereby arranging the target shot region at the imprint position.

In step S4, a contact process of bringing the mold 10 into contact with the imprint material 60 on the target shot region of the substrate 1 (on the substrate) is performed. More specifically, the linear actuator 15 is driven to move the mold stage 22 in the −Z direction (that is, lower the mold stage 22), thereby bringing the mold 10 held by the mold chuck 11 into contact with the imprint material 60 on the target shot region of the substrate 1. Note that, instead of moving the mold stage 22, the mold 10 and the imprint material 60 may be brought into contact by moving the substrate holding unit 23 in the +Z direction (that is, lifting the substrate holding unit 23), or moving both the mold stage 22 and the substrate holding unit 23.

In step S5, in a state in which the mold 10 is in contact with the imprint material 60 on the target shot region of the substrate 1, it is determined whether the force (press force (contact force)) for pressing the mold 10 against the substrate 1 (imprint material 60) is appropriate (within a predetermined range). The press force generated in the state in which the mold 10 is in contact with the imprint material 60 can be obtained from the operation amount of the linear actuator 15. If the press force is not appropriate, the process transitions to step S6. If the press force is appropriate, the process transitions to step S7.

In step S6, the position of the mold 10 is adjusted. More specifically, based on the operation amount of the linear actuator 15, the tilt of the mold chuck 11 is adjusted using the mold stage 22 or the Z-direction position of the mold 10 is adjusted using the linear actuator 15 to make the press force appropriate.

In step S7, alignment between the mold 10 (pattern region P thereof) and the substrate 1 (target shot region thereof) is performed. More specifically, first, alignment marks respectively provided in the mold 10 and the substrate 1 are detected to obtain the relative positional shift amount between the mold 10 and the substrate 1. Then, the mold 10 and the substrate 1 are aligned by driving the XY stage and the 0 stage 3 such that the relative positional shift amount between the mold 10 and the substrate 1 falls within an allowable range.

In step S8, in the state in which the mold 10 is in contact with the imprint material 60 on the target shot region of the substrate 1, a curing process of curing the imprint material 60 is performed. More specifically, after the alignment between the mold 10 and the substrate 1, light is emitted from the irradiation unit IU via the mold 10 to the entire imprint material 60 on the target shot region (the entire shot region of the substrate 1 is set as the irradiation region and exposed), thereby curing the imprint material 60.

In step S9, a separation process of separating the mold 10 from the cured imprint material 60 on the target shot region of the substrate 1 is performed. More specifically, the mold stage 22 is moved in the +Z direction (that is, the mold stage 22 is lifted) by driving the linear actuator 15, thereby separating the mold 10 held by the mold chuck 11 from the imprint material 60 on the target shot region of the substrate 1. Note that, instead of moving the mold stage 22, the mold 10 may be separated from the imprint material 60 by moving the substrate holding unit 23 in the −Z direction (that is, lowering the substrate holding unit 23) or moving both the mold stage 22 and the substrate holding unit 23.

In step S10, it is determined whether the pattern of the imprint material 60 has been formed in all the shot regions of the substrate 1. If the pattern of the imprint material 60 has not been formed in all the shot regions of the substrate 1, the process returns to step S1 to form the pattern of the imprint material 60 in the next target shot region. If the pattern of the imprint material 60 has been formed in all the shot regions of the substrate 1, the process transitions to step S11.

In step S11, by driving the XY stage 4, the substrate 1 with the pattern of the imprint material 60 formed in all the shot regions is arranged at a predetermined position for unloading the substrate 1, and the imprint process for one substrate 1 is terminated.

Here, in the alignment between the mold 10 and the substrate 1 (step S7), due to the influence of the viscosity of the imprint material 60, a shearing force is generated in the imprint material 60 existing between the mold 10 and the substrate 1. The shearing force generated in the imprint material 60 increases as the residual film thickness of the imprint material 60 decreases, and decreases as the residual film thickness of the imprint material 60 increases. Note that the residual film thickness of the imprint material 60 is the film thickness of the imprint material 60 existing between the mold 10 and the substrate 1 in the state in which the mold 10 is in contact with the imprint material 60. If an underlying layer is formed on the substrate 1, the residual film thickness of the imprint material 60 is the film thickness of the imprint material 60 exiting between the mold 10 and the underlying layer. The shearing force generated in the imprint material 60 has an effect of reducing the relative vibration between the mold 10 and the substrate 1 caused by disturbance vibration, thereby improving the alignment accuracy between the mold 10 and the substrate 1 and improving the overlay accuracy. However, if the shearing force excessively increases, the residual stress increases when curing the imprint material 60 on the substrate. In this case, if the residual stress is relieved by separating the mold 10 from the cured imprint material 60 on the substrate, a distortion occurs, and this can cause degradation of the overlay accuracy between the mold 10 and the substrate 1. Therefore, in order to improve the overlay accuracy between the mold 10 and the substrate 1, it is necessary to generate an appropriate shearing force in the imprint material 60 in the state in which the mold 10 is in contact with the imprint material 60.

FIGS. 3A and 3B are views each showing the section including the mold 10, the substrate 1, the underlying layer 70, and the imprint material 60 at the time of alignment between the mold 10 and the substrate 1 (step S7). FIG. 3A shows a case where the thickness of the underlying layer 70 is small, and FIG. 3B shows a case where the thickness of the underlying layer 70 is large. Since the underlying layer 70 is the layer formed on the surface of the substrate 1 as has been described above, the unevenness (shape) of the surface of the underlying layer 70 is influenced by the surface pattern (unevenness) existing in the substrate 1, that is, the underlying pattern. Hence, in the case where the thickness of the underlying layer 70 is small, the influence of the underlying pattern of the substrate 1 increases. Thus, as shown in FIG. 3A, the unevenness of the surface of the underlying layer 70 increases. On the other hand, in the case where the thickness of the underlying layer 70 is large, the influence of the underlying pattern of the substrate 1 decreases. Thus, the unevenness of the surface of the underlying layer 70 decreases as shown in FIG. 3B.

Assume that, in the respective states shown in FIGS. 3A and 3B, the imprint material 60 is supplied onto the substrate 1 in the same supply amount from the supply unit 18. In this case, if the thickness of the underlying layer 70 is small, the unevenness of the surface thereof increases, so that the residual film thickness of the imprint material 60 decreases (FIG. 3A). If the thickness of the underlying layer 70 is large, the unevenness of the surface thereof decreases, so that the residual film thickness of the imprint material 60 increases (FIG. 3B). Accordingly, even if the supply amount of the imprint material 60 is the same, if the thickness of the underlying layer 70 is small and the residual film thickness of the imprint material 60 is small, a large shearing force is generated as compared to the case where the thickness of the underlying layer 70 is large and the residual film thickness of the imprint material 60 is large. For example, if an appropriate shearing force is generated in the case where the thickness of the underlying layer 70 is small and the residual film thickness of the imprint material 60 is small (FIG. 3A), an insufficient shearing force is generated in the case where the thickness of the underlying layer 70 is large and the residual film thickness of the imprint material 60 is large (FIG. 3B). On the other hand, if an appropriate shearing force is generated in the case where the thickness of the underlying layer 70 is large and the residual film thickness of the imprint material 60 is large (FIG. 3B), an excessive shearing force is generated in the case where the thickness of the underlying layer 70 is small and the residual film thickness of the imprint material 60 is small (FIG. 3A).

To solve this problem, this embodiment provides a technique that contributes an improvement of the overlay accuracy by suppressing degradation of the overlay accuracy between the mold 10 and the substrate 1 caused by the shearing force generated in the imprint material 60 existing between the mold 10 and the underlying layer 70. More specifically, a technique is provided which generates an appropriate shearing force (target shearing force) in the imprint material 60 existing between the mold 10 and the underlying layer 70 in the state in which the mold 10 is in contact with the imprint material 60 on the substrate.

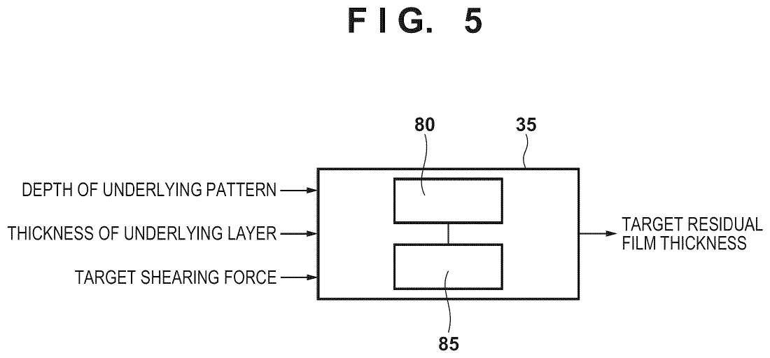

In order to implement this technique, the control unit 35 includes, as functional modules, an obtainment unit 80 and a calculation unit 85 as shown in FIG. 5. Note that the obtainment unit 80 is not limited to be formed integrally with the control unit 35 (that is, as the functional module of the control unit 35), and may be formed separately from the control unit 35. FIG. 5 is a view showing an example of the functional modules of the control unit 35.

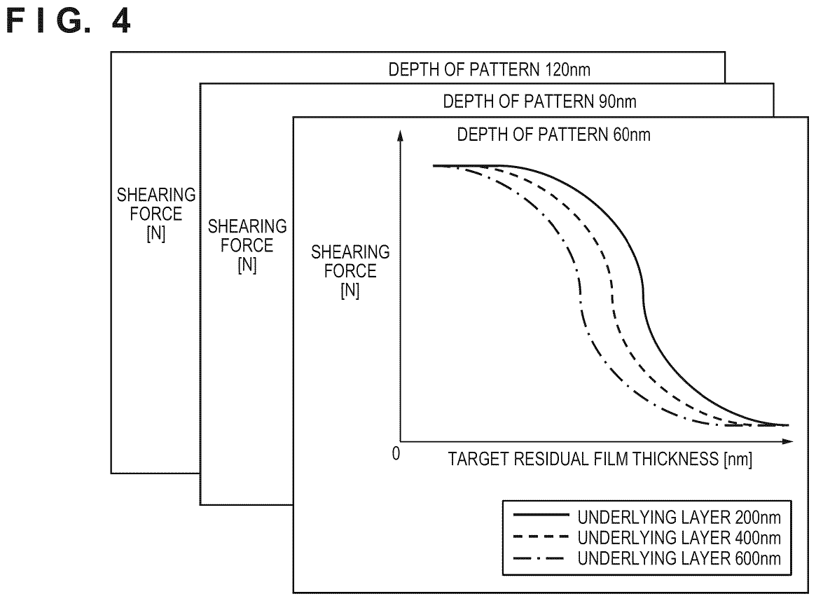

The obtainment unit 80 includes a storage unit such as a memory, and obtains and stores the data tables shown in FIG. 4. The data table shown in FIG. 4 represents information indicating the shearing force generated depending on the differences in the parameter concerning the geometric shape of the underlying pattern of the substrate 1, the parameter concerning the thickness of the underlying layer 70, and the residual film thickness of the imprint material 60 on the substrate. In other words, this information indicates the relationship among the parameter concerning the geometric shape of the underlying pattern, the parameter concerning the thickness of the underlying layer 70, the parameter concerning the residual film thickness of the imprint material 60, and the parameter concerning the shearing force generated in the imprint material 60. The parameter concerning the geometric shape of the underlying pattern includes, for example, the depth of the underlying pattern. The parameter concerning the thickness of the underlying layer 70 includes, for example, the thickness of the underlying layer 70 formed on the underlying pattern of the substrate 1. The parameter concerning the residual film thickness of the imprint material 60 includes, for example, the residual film thickness of the imprint material 60 existing between the mold 10 and the underlying layer 70 in the state in which the mold 10 is in contact with the imprint material 60 on the substrate. The parameter concerning the shearing force includes, for example, the shearing force (magnitude thereof) generated in the imprint material 60 in the state in which the mold 10 is in contact with the imprint material 60 on the substrate. Hence, in this embodiment, the data table shown in FIG. 4 represents the information indicating the relationship between the depth of the underlying pattern, the thickness of the underlying layer 70, the residual film thickness of the imprint material 60 existing between the mold 10 and the underlying layer 70, and the shearing force generated in the imprint material 60.

The calculation unit 85 calculates, based on the data table obtained and stored by the obtainment unit 80, that is, the data table shown in FIG. 4, the residual film thickness of the imprint material 60 to be formed on the underlying layer 70 formed on the underlying pattern of the substrate 1. Here, the residual film thickness of the imprint material 60 to be formed on the underlying layer 70 is the target residual film thickness (target film thickness) of the imprint material 60 required for generating the appropriate shearing force (target shearing force) in the imprint material 60. As shown in FIG. 5, when the depth of the underlying pattern of the substrate 1, the thickness of the underlying layer 70, and the target shearing force are input, the calculation unit 85 outputs the target residual film thickness of the imprint material 60 in the state in which the mold 10 is in contact with the imprint material 60. In this manner, when the depth of the underlying pattern of the substrate 1, the thickness of the underlying layer 70, and the target shearing force are input, the calculation unit 85 refers to the data table shown in FIG. 4, and decides the target residual film thickness of the imprint material 60 for generating the target shearing force in the imprint material 60.

Once the target residual film thickness of the imprint material 60 is decided by the calculation unit 85, in the imprint process, the control unit 35 (calculation unit 85) controls supply of the imprint material 60 in accordance with the target residual film thickness. More specifically, in the process of arranging the imprint material 60 (step S2), the control unit 35 controls supply of the imprint material 60 onto the underlying layer 70 such that the residual film thickness of the imprint material 60 in the state in which the mold 10 is in contact with the imprint material 60 on the substrate achieves the target residual film thickness. For example, if the imprint material 60 is supplied from the supply unit 18, the control unit 35 controls supply of the imprint material 60 from the supply unit 18 such that the residual film thickness of the imprint material 60 in the state in which the mold 10 is in contact with the imprint material 60 on the substrate achieves the target residual film thickness. On the other hand, if the imprint material 60 is supplied from a spin coater or a slit coater, the control unit 35 may control supply of the imprint material 60 by the spin coater or the slit coater in accordance with the target residual film thickness of the imprint material 60.

Here, an example of the control of supply of the imprint material 60 by the control unit 35 will be described. First, the control unit 35 decides at least one of the supply amount of the imprint material 60 and the position (supply position) to supply the imprint material 60 required for the residual film thickness of the imprint material 60 to achieve the target residual film thickness. Note that, when deciding the supply amount and supply position of the imprint material 60, the pattern of the mold 10 is preferably considered. For example, when deciding the supply amount of the imprint material 60, the capacity of the concave portion of the pattern of the mold 10 (that is, the capacity of the imprint material 60 to be filled into the concave portion) is preferably considered. When deciding the supply position of the imprint material 60, the density of supply position may be varied in accordance with the direction of the pattern of the mold 10. Once the supply amount and supply position of the imprint material 60 are decided, the control unit 35 controls supply of the imprint material 60 onto the underlying layer 70 such that the imprint material 60 is supplied in the decided supply amount at the decided supply position. Note that, in practice, the control unit 35 generally generates a drop pattern including the information indicating the supply amount and supply position of the imprint material 60, and the supply unit 18 generally supplies the imprint material 60 in accordance with the drop pattern generated by the control unit 35.

In this embodiment, in the data table shown in FIG. 4, the depth of the underlying pattern is used as the parameter concerning the geometric shape of the underlying pattern, but the pitch of the underlying pattern or the like may be used. The depth of the underlying pattern includes the average value, maximum value, minimum value, and the like of the depth of the underlying pattern, and the pitch of the underlying pattern includes the average value, maximum value, minimum value, and the like of the pitch of the underlying pattern.

The geometric shape of the pattern of the mold 10, that is, at least one of the depth of the pattern of the mold 10 and the pitch of the pattern of the mold 10 may influence the shearing force generated in the imprint material 60 existing between the mold 10 and the underlying layer 70. In this case, the parameter concerning the geometric shape of the pattern of the mold 10 may be included in the data table shown in FIG. 4. Then, when the depth (or pitch) of the underlying pattern, the depth (or pitch) of the pattern of the mold 10, the thickness of the underlying layer 70, and the target shearing force are input, the calculation unit 85 may output the target residual film thickness of the imprint material 60.

As has been described above, according to this embodiment, in the state in which the mold 10 is in contact with the imprint material 60 on the substrate, the residual film thickness of the imprint material 60 can achieve the target residual film thickness required for generating the appropriate shearing force (target shearing force) in the imprint material 60. Hence, it is possible to suppress degradation of the overlay accuracy between the mold 10 and the substrate 1 caused by the shearing force generated in the imprint material 60 existing between the mold 10 and the underlying layer 70, thereby improving the overlay accuracy.

In this embodiment, the imprint apparatus 100 has been taken as an example and described. However, an information processing apparatus (an information processing apparatus including the calculation unit 85) that outputs the residual film thickness (target residual film thickness) of the imprint material 60 to be formed on the underlying layer 70 formed on the substrate 1 also forms one aspect of the present invention.

Next, a method for obtaining the data tables shown in FIG. 4 will be described. To obtain the data tables shown in FIG. 4, it is necessary to variously change the depth of the underlying pattern, the film thickness of the underlying layer 70, and the residual film thickness of the imprint material 60, and measure (obtain) the shearing force generated during this.

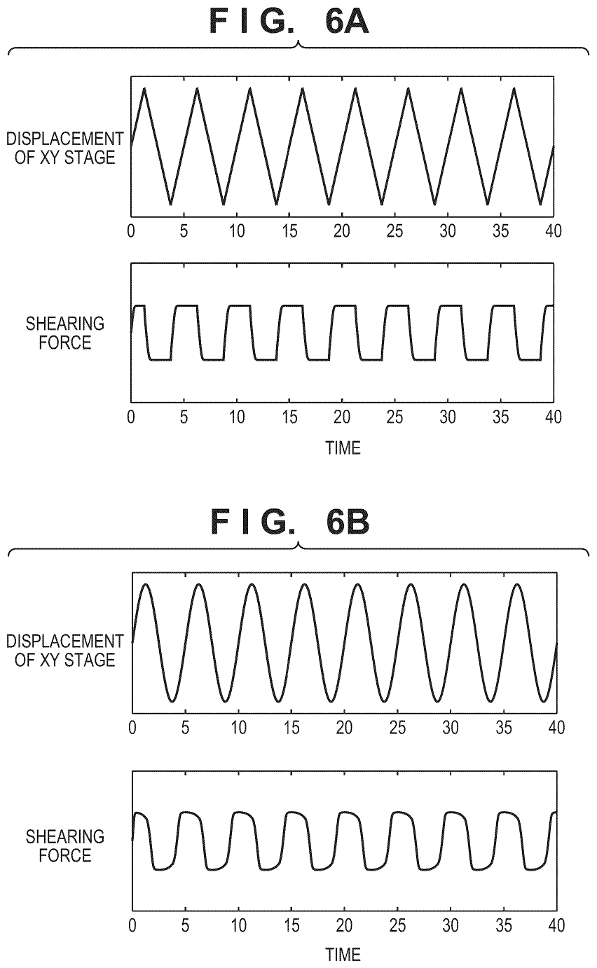

For example, the state in which the mold 10 is in contact with the imprint material 60 on the substrate is set. Then, while changing each of the depth of the underlying pattern, the thickness of the underlying layer, and the residual film thickness of the imprint material 60, the operation amount of the XY stage 4 (linear motor 19) is obtained during driving of the XY stage 4 in accordance with the triangular wave profile as shown in FIG. 6A. The operation amount of the XY stage 4 can be obtained by monitoring the drive command value (current command value) which is given from the control unit 35 to the linear motor 19 to drive the XY stage 4 to the target position. In other words, the control unit 35 also functions as an operation amount obtainment unit that obtains the operation amount of the XY stage 4. The value obtained by multiplying the operation amount of the XY stage 4 by a thrust constant represents the force required for driving the XY stage 4 against the shearing force generated in the imprint material 60. Hence, this is equal to the shearing force generated in the imprint material 60. Accordingly, from the result obtained by obtaining the operation amount of the XY stage 4 while the XY stage 4 is driven in accordance with the triangular wave drive profile, more specifically, by converting the operation amount of the XY stage 4 into the shearing force, the data table shown in FIG. 4 can be obtained. Note that, when obtaining the operation amount of the XY stage 4 (linear motor 19), the XY stage 4 may be driven in accordance with a sine wave drive profile as shown in FIG. 6B instead of the triangular wave drive profile. Each of FIGS. 6A and 6B is a view showing the relationship between the displacement (drive) of the XY stage 4 and the shearing force generated in the imprint material 60 (the operation amount of the XY stage 4).

The pattern of a cured product formed using the imprint apparatus 100 (imprint method) in the embodiment is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

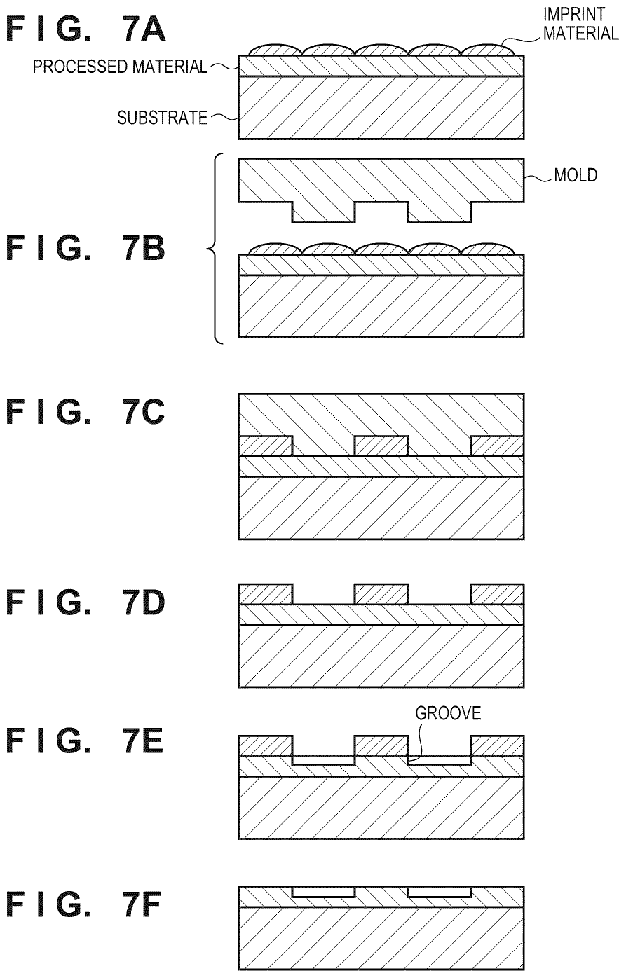

Next, description regarding a detailed method of manufacturing an article is given. As illustrated in FIG. 7A, the substrate such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 7B, a side of the mold for imprint with a projection and groove pattern is formed on and caused to face the imprint material on the substrate. As illustrated in FIG. 7C, the substrate to which the imprint material is applied is brought into contact with the mold, and a pressure is applied. The gap between the mold and the processed material is filled with the imprint material. In this state, when the imprint material is irradiated with light serving as curing energy through the mold, the imprint material is cured.

As shown in FIG. 7D, after the imprint material is cured, the mold is released from the substrate. Thus, the pattern of the cured product of the imprint material is formed on the substrate. In the pattern of the cured product, the groove of the mold corresponds to the projection of the cured product, and the projection of the mold corresponds to the groove of the cured product. That is, the projection and groove pattern of the mold is transferred to the imprint material.

As shown in FIG. 7E, when etching is performed using the pattern of the cured product as an etching resistant mask, a portion of the surface of the processed material where the cured product does not exist or remains thin is removed to form a groove. As shown in FIG. 7F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2023-142378 filed on Sep. 1, 2023, which is hereby incorporated by reference herein in its entirety.

What is claimed is:

1. An imprint apparatus that performs an imprint process of forming, by using a mold, a pattern of an imprint material on a layer formed on a surface pattern existing in a substrate, the apparatus comprising:
an obtainment unit configured to obtain information indicating a relationship among a geometric shape of the surface pattern, a thickness of the layer, a film thickness of the imprint material existing between the mold and the layer in a state in which the mold is in contact with the imprint material, and a shearing force generated in the imprint material in the state; and
a control unit configured to control the imprint process,
wherein the control unit
includes a calculation unit configured to, if the geometric shape of the surface pattern, the thickness of the layer, and a target shearing force are input, output a target film thickness of the imprint material required for generating the target shearing force in the imprint material based on the information obtained by the obtaining unit, and
controls supply of the imprint material onto the layer such that the film thickness of the imprint material in the state achieves the target film thickness in the imprint process.

2. The apparatus according to claim 1, wherein
the obtainment unit includes a storage unit configured to store the information.

3. The apparatus according to claim 1, wherein
the geometric shape of the surface pattern includes at least one of a depth of the surface pattern and a pitch of the surface pattern.

4. The apparatus according to claim 1, wherein
the information indicates a relationship among a geometric shape of a pattern of the mold, a geometric shape of the surface pattern, a thickness of the layer, a film thickness of the imprint material existing between the mold and the layer in a state in which the mold is in contact with the imprint material, and a shearing force generated in the imprint material in the state, and
if the geometric shape of the pattern of the mold, the geometric shape of the surface pattern, the thickness of the layer, and a target shearing force are input, the calculation unit outputs the target film thickness based on the information.

5. The apparatus according to claim 4, wherein
the geometric shape of the pattern of the mold includes at least one of a depth of the pattern of the mold and a pitch of the pattern of the mold.

6. The apparatus according to claim 1, further comprising:
a stage configured to hold and drive the substrate; and
an operation amount obtainment unit configured to obtain an operation amount of the stage,
wherein the obtainment unit obtains the information from a result obtained by obtaining the operation amount by the operation amount obtainment unit during driving of the stage in accordance with a triangular wave drive profile while changing each of the geometric shape of the surface pattern, the thickness of the layer, and the film thickness of the imprint material.

7. The apparatus according to claim 1, further comprising:
a stage configured to hold and drive the substrate; and
an operation amount obtainment unit configured to obtain an operation amount of the stage,
wherein the obtainment unit obtains the information from a result obtained by obtaining the operation amount by the operation amount obtainment unit during driving of the stage in accordance with a sine wave drive profile while changing each of the geometric shape of the surface pattern, the thickness of the layer, and the film thickness of the imprint material.

8. The apparatus according to claim 6, wherein
the obtainment unit obtains the information by converting the operation amount obtained by the operation amount obtainment unit into the shearing force.

9. The apparatus according to claim 1, wherein
the control unit decides a supply amount of the imprint material required to make the film thickness of the imprint material in the state achieve the target film thickness, and controls supply of the imprint material onto the layer such that the imprint material is supplied in the supply amount.

10. The apparatus according to claim 1, wherein
the control unit decides, based on the target film thickness, a supply position where the imprint material is to be supplied onto the layer, and controls supply of the imprint material onto the layer such that the imprint material is supplied to the supply position.

11. The apparatus according to claim 1, further comprising a supply unit configured to supply the imprint material onto the layer,
wherein in the imprint process, the control unit controls supply of the imprint material by the supply unit such that the film thickness of the imprint material in the state achieves the target film thickness.

12. An imprint method for performing an imprint process of forming, by using a mold, a pattern of an imprint material on a layer formed on a surface pattern existing in a substrate, the method comprising:
obtaining information indicating a relationship among a geometric shape of the surface pattern, a thickness of the layer, a film thickness of the imprint material existing between the mold and the layer in a state in which the mold is in contact with the imprint material, and a shearing force generated in the imprint material in the state; and
controlling the imprint process,
wherein, in the controlling the imprint process,
if the geometric shape of the surface pattern, the thickness of the layer, and a target shearing force are input, a target film thickness of the imprint material required for generating the target shearing force in the imprint material is obtained based on the information, and
in the imprint process, supply of the imprint material onto the layer is controlled such that the film thickness of the imprint material in the state achieves the target film thickness.

13. An information processing apparatus that, in an imprint process of forming, by using a mold, a pattern of an imprint material on a layer formed on a surface pattern existing in a substrate, outputs a film thickness of the imprint material to be formed on the layer, the apparatus comprising
a calculation unit configured to, if a geometric shape of the surface pattern, a thickness of the layer, and a target shearing force are input, based on information indicating a relationship among a geometric shape of the surface pattern, a thickness of the layer, a film thickness of the imprint material existing between the mold and the layer in a state in which the mold is in contact with the imprint material, and a shearing force generated in the imprint material in the state, output a target film thickness of the imprint material required for generating the target shearing force in the imprint material.

14. The apparatus according to claim 13, further comprising a storage unit configured to store the information.

15. An imprint apparatus that performs an imprint process of forming, by using a mold, a pattern of an imprint material on a layer formed on a surface pattern existing in a substrate, the apparatus comprising:
an obtainment unit configured to obtain a target film thickness of the imprint material output from an information processing apparatus defined in claim 13; and
a control unit configured to control supply of the imprint material onto the layer such that a film thickness of the imprint material in the state achieves the target film thickness in the imprint process.

16. An article manufacturing method comprising:
forming a pattern on a substrate using an imprint method defined in claim 12;
processing the substrate on which the pattern is formed in the forming; and
manufacturing an article from the processed substrate.
